(19) United States
(12) Patent Application Publication
(10) Pub. No.: US 2026/0005683 A1
(43) Pub. Date: Jan. 1, 2026

(54) COMPARATOR WITH KICKBACK COMPENSATION

(71) Applicants: Ashish KUMAR, Ghaziabad (IN); Dharmaray NEDALGI, Bangalore (IN); Srikanth Samatha JATAVALLABHULA, Bangalore (IN)

(72) Inventors: Ashish KUMAR, Ghaziabad (IN); Dharmaray NEDALGI, Bangalore (IN); Srikanth Samatha JATAVALLABHULA, Bangalore (IN)

(21) Appl. No.: 18/759,442

(22) Filed: Jun. 28, 2024

(51) Int. Cl. H03K 5/24

(52) U.S. Cl. CPC H03K 5/249

(57) ABSTRACT

In some embodiments, a compensation circuit is provided to reduce adverse effects of kickback voltages at reference inputs for comparator circuits in receiver cells.

### TECHNICAL FIELD

Embodiments of the invention relate to the field of integrated circuits; and more particularly, to receiver circuits in interconnect interface circuits.

### BRIEF DESCRIPTION OF THE DRAWINGS

The disclosure may best be understood by referring to the following description and accompanying drawings that are used to illustrate embodiments of the invention. In the drawings:

FIG. 1A is a schematic diagram showing a portion of a receiver cell.

FIG. 1B is a schematic diagram showing a sense amplifier for the receiver circuit of FIG. 1A.

FIG. 1C is a signal diagram showing signals for the sense amplifier circuit of FIG. 1B.

FIGS. 2A and 2B are diagrams showing a portion of a single-ended receiver cell comprising a sense amplifier circuit in accordance with some embodiments.

FIG. 2C is a signal diagram showing signals for the sense amplifier circuit of FIG. 2B in accordance with some embodiments.

FIGS. 3A and 3B are diagrams showing a portion of an Rx cell comprising a sense amplifier in accordance with some additional embodiments.

FIGS. 4A and 4B are diagrams showing a portion of an Rx cell comprising a sense amplifier in accordance with yet additional embodiments.

FIG. 5 is a diagram showing first and second dies comprising die to die lane links with receiver cells that have KBC circuits in accordance with some embodiments.

FIG. 6 is a diagram showing a multi-die memory stack apparatus in accordance with some embodiments.

FIG. 7 illustrates an example computing system in accordance with some embodiments.

### DETAILED DESCRIPTION

Some integrated circuit (IC) dies use single-ended interconnects to communicate with other dies in a computing system. They typically use receivers that employ sense amplifiers (or comparators) to interpret data received over a link through an interconnect interface. However, it is becoming ever more of a challenge to process received data given higher data transfer speed and reduced power consumption expectations. For example, with some HBM (High Bandwidth Memory) links, data may be sent and received over single-ended interconnect lanes between dies using, for example, a nominal 400 mV supply at 6.4 Gbps. On the receiver side, two separate, parallel sense amplifiers each clocked at 3.2 GHZ, may be used to extract data from the bit stream. With such low voltages and high frequencies, it is difficult to design receivers that can accurately and reliably operate under these conditions.

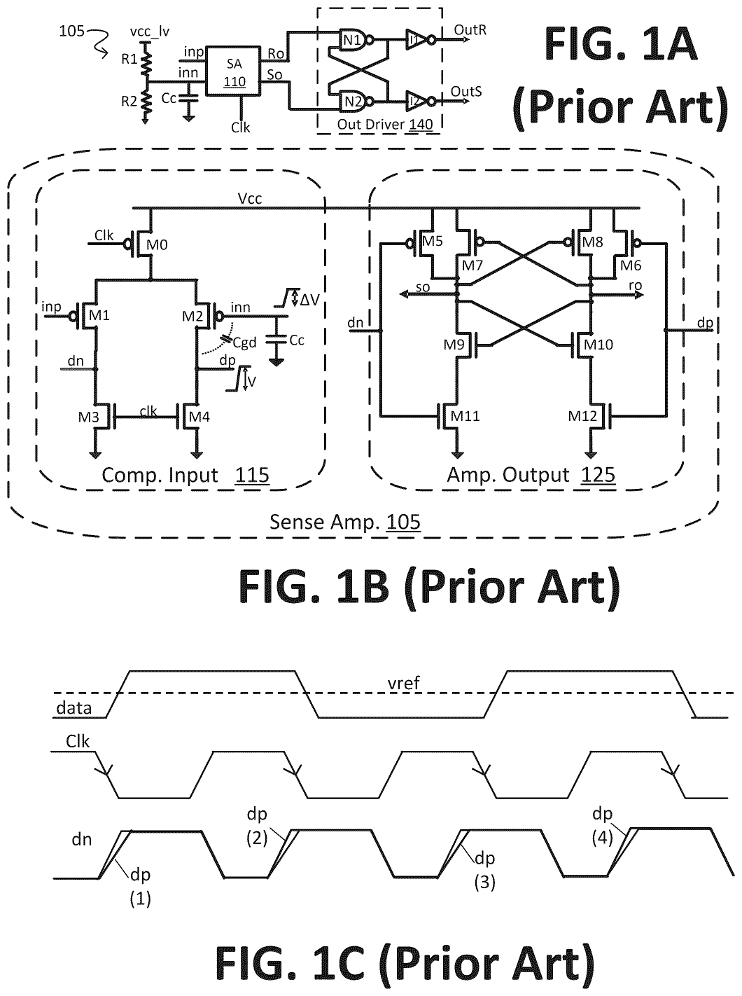

FIG. 1A is a schematic diagram showing a portion of a receiver (Rx) cell in a single-ended link. The Rx cell comprises a sense amplifier (SA) circuit 110 coupled to an output driver circuit 140, along with divider resistors R1, R2, and decoupling (or compensation) capacitor Cc, coupled together as shown. The divider resistors provide a voltage-divided reference voltage (inn) to a first input of the SA, while the received data signal (inp) is coupled to a second input of the SA. The SA, also referred to as a comparator, compares the voltage levels at the two inputs and asserts (e.g., high) a first one of its outputs (So) and de-asserts at a second output (Ro), if inp is greater than inn, indicating a logic ′1 for the data bit. Otherwise, if inn is greater than inp, the Ro output asserts, and the So output de-asserts.

The So and Ro outputs are coupled to inputs of the output driver, which comprises cross-coupled Nand gates (N1, N2) and inverters (11, 12), as shown, to drive the SA outputs Ro, So, and provide them as buffered outputs OutR, OutS, respectively.

In the depicted example, divider resistors R1, R2 are supplied through Vcc_lv, e.g., an HBM low-voltage supply of 0.4 V. From this supply, the resistors are typically configured to provide the inn reference at ½ Vcc_lv, e.g., 0.2 V. The SA compares the received signal (inp) with the 0.2 V reference to determine the logic level of the bit (or data) signal for the given clock sample. Therefore, with this 0.4 V Vcc_lv example, the SA should be able to interpret a received pad voltage of less than 0.2 V as a logic ′0 and a voltage greater than 0.2 V as a logic ′1.

FIG. 1B is a schematic diagram showing the sense amplifier 110 of FIG. 1A in greater detail. The SA includes a dynamic comparator input section 115 and an amplifying output section 125 as is shown. The SA is configured to operate as a dynamic latch (e.g., as a so-called strongarm latch). The comparator input circuit 115 includes P-type evaluate transistor M0, precharge N-type transistors M3, M4 and input transistors (P-type in this example) M1, M2. (Note that this circuit is designed to compare the data signal off of a falling clock edge, but other versions of this circuit may use different P/N combinations, for example, to sample off of a rising edge. Along these lines, the term “precharge” refers to controlling a node to be evaluated, nodes dn and dp in this example, to be at a certain deterministic charge state, e.g., Vcc or ground. With this example, during a precharge clock pcomprisese, the N-type precharge transistors M3, M4 may actually discharge the dp, dn nodes to place them at a low state, ready for the falling clock edge evaluation pcomprisese.)

The resistor dividers (not shown in this figure) provide the reference voltage at the gate of M2, the inn node to be compared by the circuit against the voltage at the gate input of M1, the inp node. They are typically fairly large so as to reduce their power consumption. (This circuit may be implemented in thousands of instantiations in a given die interface.)

The amplifier output (or amplifier) circuit 125 is coupled to the comparator circuit 115 through the dn and dp nodes. It serves to evaluate and latch, the compared result. The amplifier circuit 125 includes differential input transistors M5, M6, M11, and M12 and cross-coupled transistors M7-M10, coupled within the input transistors, as shown, to catch and stabilize (or latch) the comparison result as provided through nodes dp, dn.

When the clock (Clk) is high, the comparator section is in a precharge state with the indicated dp and dn nodes at low levels causing both Ro and So outputs to be at high (logic ′1) states. When the clock transitions from high to low (falling edge), transistor M0 turns On and the dp and dn nodes move from logic ′0 states to logic ′1 states as M3 and M4 are turned Off. This is illustrated in the signal diagram of FIG. 1C. While moving from logic ′0 to logic ′1 states, dp and dn have different slopes, depending on the received data and reference voltages at the gates of input transistors M1 and M2. The difference between the dp and dn slopes is then sensed by the amplifier section and provided as either a logic ′0 or a logic ′1 at the So/Ro outputs.

In many implementations, the sizes of the comparator input transistors M1, M2 are relatively large, e.g., twice as wide as M0 and four times as wide as M3, M4) to reduce the overall offset of the input section. Unfortunately, this increases the overlap capacitances (Cgd) at the input transistors. This results in a so-called kick-back voltage being added to the input nodes (inn, inp) when the clock transitions, from high to low. The effect is not the same, however, for both nodes because the capacitive RC time constant for the inn (reference) input is higher as a result of the higher RC resistance due to the large divider resistors. This kick-back effect is indicated as “AV” in the figure. The amount of the kickback is proportional to Cgd/(Cgd+Cc).

For this example, when the circuit samples (evaluates) off of the clock's falling edge, dp transitions from 0 to Vcc (e.g., 0.8 V or so), adding the kickback voltage (AV) to the reference input (inn) and corrupting the reference input (inn), relative to the data input (inp), which affects the dn and dp slopes that are to be evaluated by the amplifier section. With the high RC time constant on the reference side, the inn node doesn't have time to return to its correct value given the high clocking frequencies (e.g., 3.2 GHZ) that may be used. This effect is illustrated in FIG. 1C, which shows how close the dn, dp slopes can be to each other and how easily their evaluated difference may be corrupted by the kickback at the reference input.

Since the kickback voltage is inversely proportional to the amount of decoupling capacitance (Cc) used in the cell, the kickback voltage should be reduced by increasing Cc. Unfortunately, however, in order to have a meaningful impact, a relatively large Cc would need to be used, substantially increasing the overall Rx cell complex area since there may be hundreds if not thousands of receiver cells in a die. A receiver section could be dominated by such large decoupling capacitors, taking up over half of the total receiver area.

Accordingly, in some embodiments, circuits are provided to counter (or compensate) for kickback voltages in comparator (e.g., sense amplifier) circuits. In some embodiments, this can allow for the reduction or even elimination of decoupling capacitors at comparator reference input nodes.

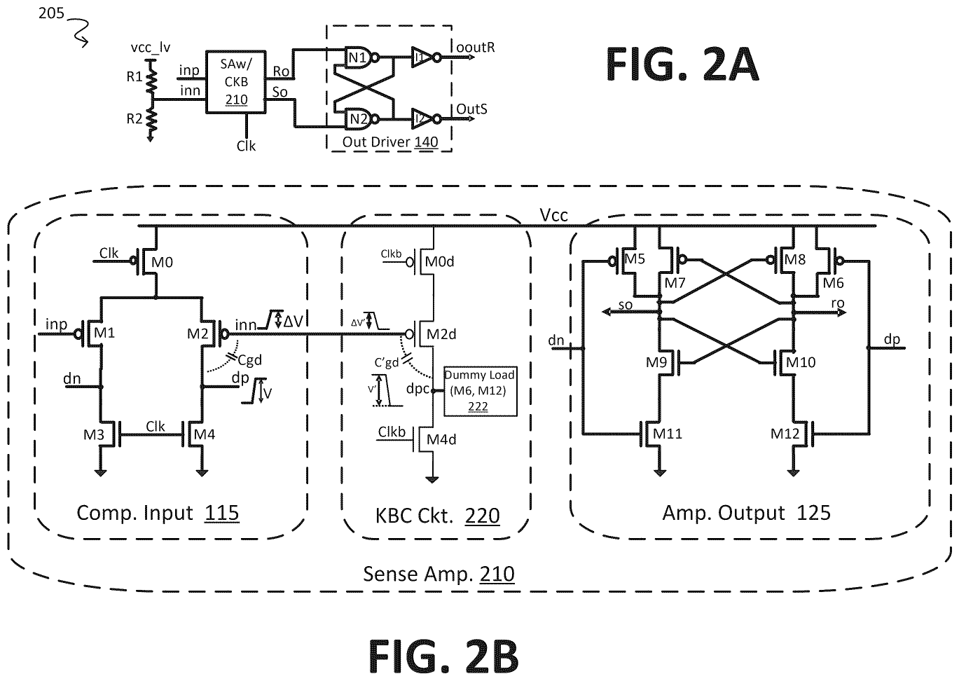

FIGS. 2A and 2B are diagrams showing a portion of a single-ended receiver cell comprising a sense amplifier circuit in accordance with some embodiments. The receiver cell (Rx cell) 205 comprises a sense amplifier (SA) circuit 210 coupled to an output driver circuit 140 and divider resistors R1, R2, coupled together as shown. The Rx cell 205 functions similar to the Rx cell described above, but it comprises a kickback compensation (KBC) circuit 220 coupled, as shown, to a comparator input circuit 115 and to an amplifier output circuit 125, to counter kick-back voltages at the reference input node (inn). In some embodiments, With the use of a KBC circuit, large decoupling capacitors (e.g., 800 fF or higher) may be reduce or even removed. As such, in this example, a decoupling capacitor is not indicated. In addition, with a KBC, in some embodiments, larger divider resistors may be used to reduce power consumption.

The depicted KBC circuit 220 comprises transistors M0d, M2d, and M4d, along with a dummy load 225, coupled as shown to the reference input node (inn). The gates of M0d and M4d are coupled to clocks (Clkb) that are complements of the clock (Clk) used for the comparator input section 115. The dummy load 222 is coupled to the KBC circuit 220 at a “dpc” node where M2d is coupled to M4d. The dummy load 222 includes components such as dummy transistors or transistor elements to match load characteristics looking into the dp node of the amplifier output circuit 140. Thus, in the depicted example, they are designed to match a load defined by the M6 and M12 gate inputs which are coupled together at the dp node. Likewise, the M0d, M2d, and M4d transistors should be sized appropriately. The M2d transistor should be matched with input transistor M2, not only to have a comparable strength, but also, to have an equivalent overlap capacitance (C′gd) with that of input transistor M2. In addition, M4d should be matched with M4, but M0d should be matched to half of M0 since it is feeding only one branch (M2d, M4d) rather than both of the M1 and M2 branches as is M0.

In operation, the kickback compensation circuit 220 produces a complementary (negative for this falling edge evaluation) kickback voltage of ΔV′ at the reference input node (inn). During the evaluation clock transition, when Clk goes low and Clkb goes high, the dp node moves from 0 V to Vcc, but also during this time, the dpc node moves from Vcc to 0 V in an opposite direction. This is illustrated in the signal diagram of FIG. 2C. In this way, the kickback compensation circuit may be able to substantially offset the kickback voltage that would otherwise be incurred at the reference input node.

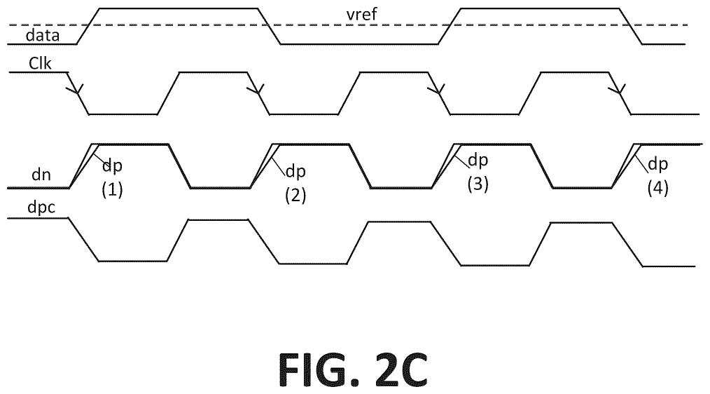

FIGS. 3A and 3B are diagrams showing a portion of an Rx cell in accordance with some additional embodiments. In this example, a decoupling capacitor (Cc), along with a KBC circuit 320, are employed. A decoupling capacitor, albeit a smaller capacitor than would otherwise have been required, may be used with the KBC circuit.

Because of the random variations in transistor sizes during fabrication, layout effects and asymmetric Clk and Clkb transitions, even with a KBC circuit, there may still be some residual kickback. Accordingly, in some embodiments, a decoupling capacitor (Cc), for example, one fourth the size of conventional implementations (e.g., 200 fF or less for previous designs using 800 fF decoupling capacitors) may be used to further reduce the residual kickback. The below table shows kickback mitigation in some circuit simulations under different configurations (Cc with no KBC, larger Cc with no KBC, and smaller Cc with KBC).

| Configuration | Kickback Voltage (ΔV) | |
|---|---|---|
| Without KBC (Cc = 200 fF) | 9 | mV |
| Without KBC (Cc = 800 fF) | 2.75 | mV |
| With KBC (Cc = 200 fF) | 0.3 | mV |

It can be seen that with the use of a KBC and a relatively small decoupling capacitor (Cc), much kickback compensation can be achieved. With some implementations, using a smaller decoupling capacitor can result in an area savings of 35% and at the same time, achieve enhanced kickback mitigation. In addition, there is little impact on power and as noted above, even more power can be saved by increasing the resistances of the divider resistors (R1, R2) without materially compromising the overall kickback compensation.

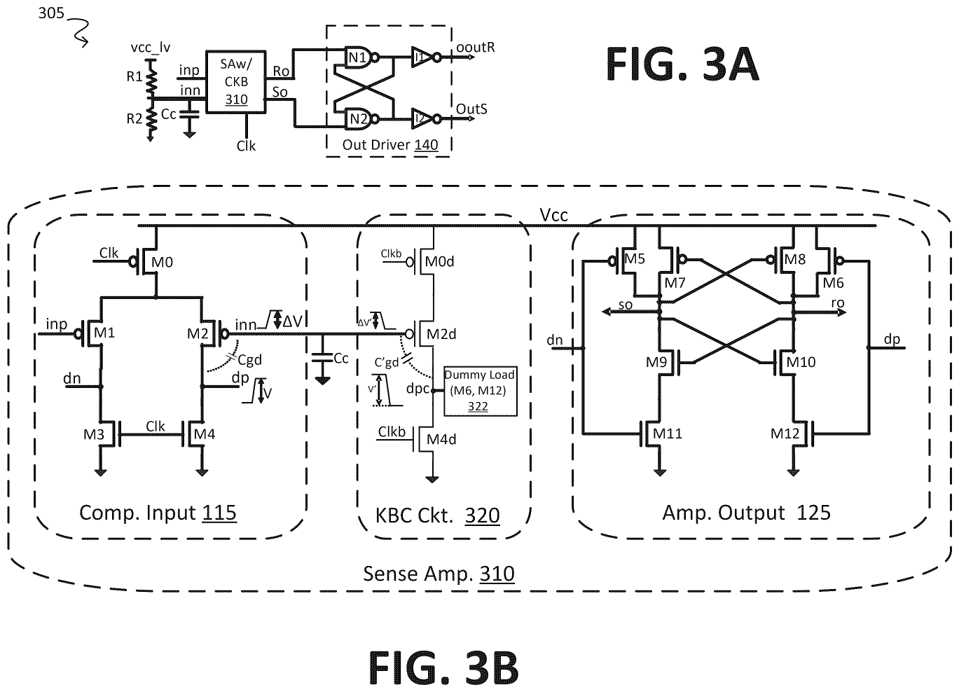

FIGS. 4A and 4B are diagrams showing a portion of an Rx cell 405 in accordance with yet additional embodiments. In this example, the receiver cell 405 comprises a sense amplifier (SA) circuit 410 coupled to an output driver circuit 140, divider resistors R1, R2 and decoupling capacitor (Cc), coupled together as shown. The Rx cell 405 uses a comparator input circuit 415 with N-type input transistors (M1, M2) and with the M0 and M3/M4 transistor types reversed. The precharge transistors M3, M4 are now P-type transistors coupled to Vcc, and the evaluation transistor M0 is an N-type transistor coupled to ground. Thus, with this configuration, the data is sampled off of a rising clock (Clk) edge instead of a falling edge. In turn, as seen in FIG. 4B, the KBC circuit transistors M0d, M2d and M4d are also reversed as compared with those of FIGS. 2B and 3B. M0d and M2d are now N-type transistors and M4d is a P-type transistor.

Using either a P-type or an N-type input transistor-pair based implementation can be advantageous over the other based on the data signal input common mode characteristics. N-type input transistor implementations are typically good for higher input common mode voltages, while P-type input transistor implementations are typically better suited for lower input common mode voltages.

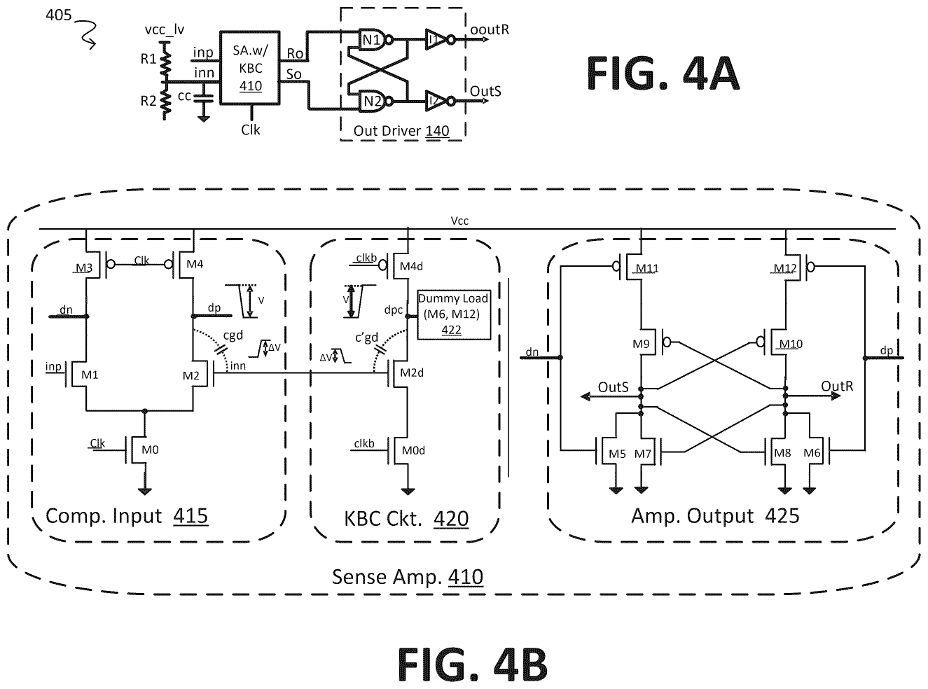

FIG. 5 is a diagram showing first and second dies comprising die to die interconnect interfaces with receiver cells that have KBC circuits in accordance with some embodiments. Die A comprises an input/output (IO) interface 101A coupled to IO interface 101B of Die B through multiple (N) lanes (Lane 1-Lane N). For each lane, Die A comprises Tx cells 502A and Rx cells 504A, while Die B comprises corresponding Tx cells 502B and Rx cells 504B to form single-ended interconnect lanes. In one or both of the dies, the receiver cells 504 also have KBC circuits 510 to enhance link performance as discussed above.

With this example, a common lane pathway (conductive path formed from wires, traces, contacts, bumps, vias, etc.) is used for data transfers in both directions. In some embodiments, a half-duplex scheme may be used or a simultaneous bidirectional fully duplex scheme may be employed. The lane links may be used in any multi-lane single-ended scheme that uses receiver comparators (e.g., sense amplifiers) with fixed references, especially with high-speed and low power implementations. They may be use for interconnect links with memory systems such as for double-data rate (DDR) schemes, High Bandwidth Memory, and non-volatile links, as well as links for communicating between other types of dies such as between GPUs (graphics processing units), accelerators, and compute processor dies.

Along these lines, the dies also include functional circuit blocks 506 (Die A) and 508 (Die B) as indicated. Depending on the roles and configurations for the dies, their functional circuit blocks (or functional circuits) 506, 508 may correspond to any circuitry that performs a particular function. A “functional block” or “component” may be a unit of logic, circuit, cell, or chip layout that is designed for a particular application or is reusable. A functional block is sometimes colloquially referred to as an IP (intellectual property) block. A few examples of functional blocks or components include processor cores, memories, caches, floating point processors, memory controllers, bus controllers, graphics processors, transceivers, network interface controllers, digital signal processors, artificial intelligence engines, display engines, video processing units, crypto engines, and other circuit blocks. One or more portions of a larger functional block can themselves be designated as functional blocks. For example, an instruction execution unit and cache controller can be functional units or components of a processor functional unit. Likewise, the dies may correspond to any type of die or multi-die package such as a processor (e.g., central processing unit, compute processor, graphics processor, applications processor, system-on-chip, system-on-package, graphics processor, vector processing unit, artificial intelligence processor, video processor, network processor, etc.), memory chip or memory package, IO extension/hub and the like.

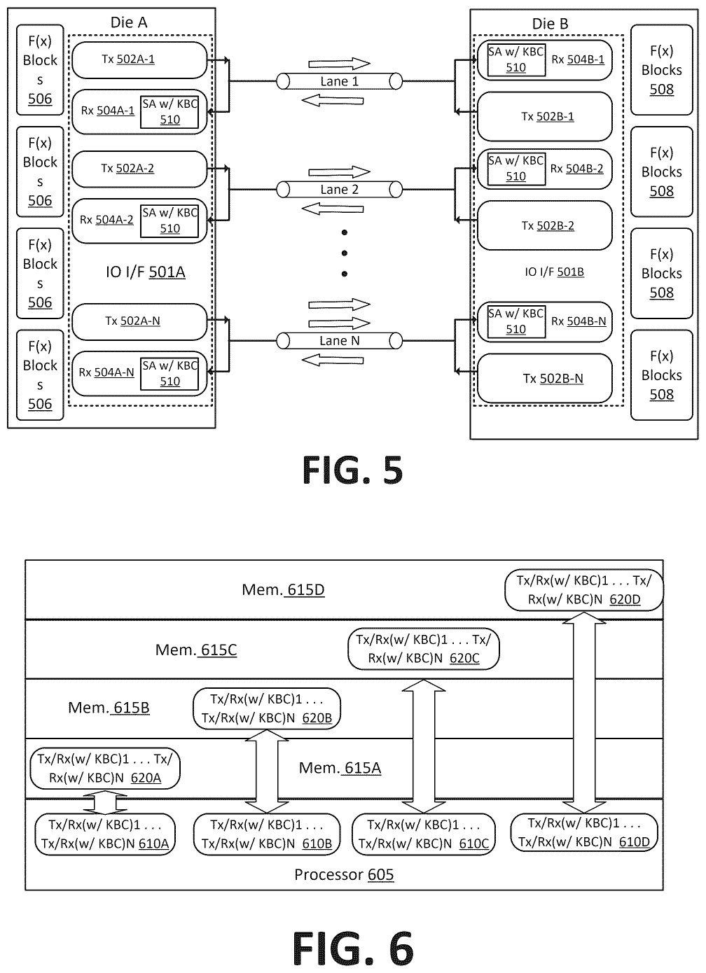

FIG. 6 is a diagram showing a multi-die memory stack apparatus in accordance with some embodiments. The apparatus includes a processor 605 and a multi-die memory stack (e.g., HBM stack module) formed from memory chips (or dies) 615 (615A-615D). The processor is communicatively linked with each memory chip 615 through separate interconnect interfaces comprising interconnect lanes with Tx/Rx cells 610 on the processor side and Tx/Rx cells 620 on the memory die side. For example, the processor is linked with memory chip 615A through Tx/Rx cells 610A and Tx/Rx cells 620A. The Rx cells, in either or both of the processor and memory dies may have KBC circuits as described herein.

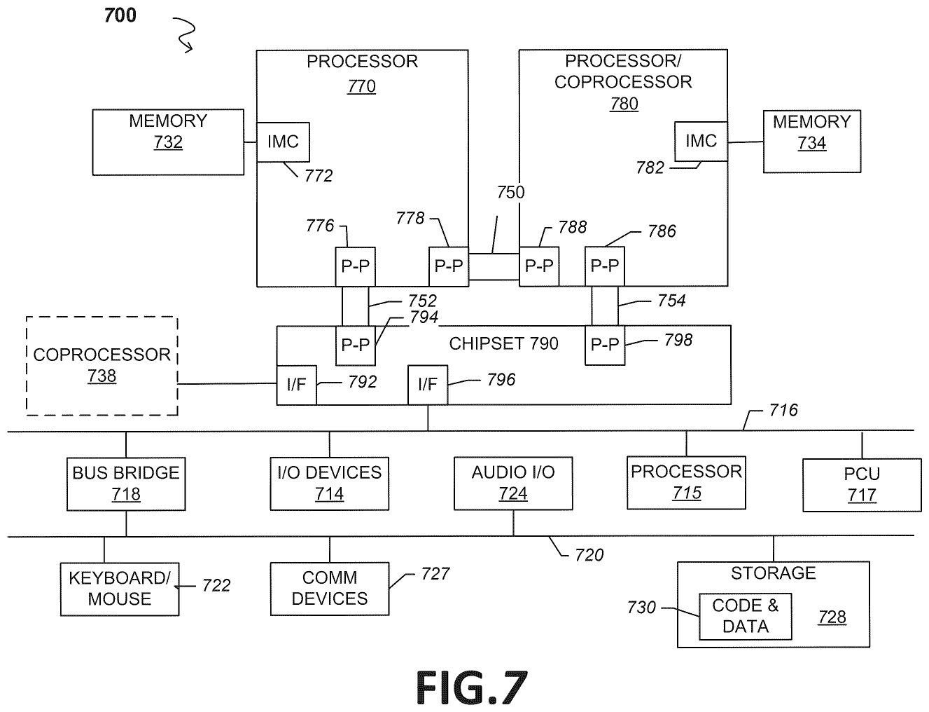

FIG. 7 illustrates an example computing system. Multiprocessor system 700 is an interfaced system and includes a plurality of processors including a first processor 770 and a second processor 780 coupled via an interface 750 such as a point-to-point (P-P) interconnect, a fabric, and/or bus. In some embodiments, this or other interfaces described herewith may include KBC circuits as described herein. In some examples, the first processor 770 and the second processor 780 are homogeneous. In some examples, first processor 770 and the second processor 780 are heterogenous. Though the example system 700 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 770 and 780 are shown including integrated memory controller (IMC) circuitry 772 and 782, respectively. Processor 770 also includes interface circuits 776 and 778, along with core sets. Similarly, second processor 780 includes interface circuits 786 and 788, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 770, 780 may exchange information via the interface 750 using interface circuits 778, 788. IMCs 772 and 782 couple the processors 770, 780 to respective memories, namely a memory 732 and a memory 734, which may be portions of main memory locally attached to the respective processors.

Processors 770, 780 may each exchange information with a network interface (NW I/F) 790 via individual interfaces 752, 754 using interface circuits 776, 794, 786, 798. The network interface 790 (e.g., one or more of an interconnect, bus, and/or fabric, and in some examples is a chipset) may optionally exchange information with a coprocessor 738 via an interface circuit 792. In some examples, the coprocessor 738 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 770, 780 or outside of both processors, yet connected with the processors via an interface such as P-P interconnect, such that either or both processors' local cache information may be stored in the shared cache if a processor is placed into a low power mode.

Network interface 790 may be coupled to a first interface 716 via interface circuit 796. In some examples, first interface 716 may be an interface such as a Peripheral Component Interconnect (PCI) interconnect, a PCI Express interconnect, or another I/O interconnect. In some examples, first interface 716 is coupled to a power control unit (PCU) 717, which may include circuitry, software, and/or firmware to perform power management operations with regard to the processors 770, 780 and/or co-processor 738. PCU 717 provides control information to one or more voltage regulators (not shown) to cause the voltage regulator(s) to generate the appropriate regulated voltage(s). PCU 717 also provides control information to control the operating voltage generated. In various examples, PCU 717 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 717 is illustrated as being present as logic separate from the processor 770 and/or processor 780. In other cases, PCU 717 may execute on a given one or more of cores (not shown) of processor 770 or 780. In some cases, PCU 717 may be implemented as a microcontroller (dedicated or general-purpose) or other control logic configured to execute its own dedicated power management code, sometimes referred to as P-code. In yet other examples, power management operations to be performed by PCU 717 may be implemented externally to a processor, such as by way of a separate power management integrated circuit (PMIC) or another component external to the processor. In yet other examples, power management operations to be performed by PCU 717 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 714 may be coupled to first interface 716, along with a bus bridge 718 which couples first interface 716 to a second interface 720. In some examples, one or more additional processor(s) 715, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 716. In some examples, second interface 720 may be a low pin count (LPC) interface. Various devices may be coupled to second interface 720 including, for example, a keyboard and/or mouse 722, communication devices 727 and storage circuitry 728. Storage circuitry 728 may be one or more non-transitory machine-readable storage media as described below, such as a disk drive or other mass storage device which may include instructions/code and data 730 and may implement the storage in some examples. Further, an audio I/O 724 may be coupled to second interface 720. Note that other architectures than the point-to-point architecture described above are possible. For example, instead of the point-to-point architecture, a system such as multiprocessor system 700 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality.

Illustrative examples of the technologies disclosed herein are provided below. An embodiment of the technologies may include any one or more, and any compatible combination of, the examples described below.

Example 1 is an apparatus that includes a comparator circuit and a KBC circuit. The comparator circuit includes first and second input transistors, the first input transistor including a first gate coupled to a reference input node, and the second input transistor including a second gate coupled to a data input node. The KBC circuit includes a first KBC transistor with a first KBC transistor gate coupled to the reference input node.

Example 2 includes the subject matter of example 1, and wherein the first input transistor comprises a first input transistor drain, the dynamic comparator circuit including a precharge transistor comprising a precharge transistor drain coupled to the first input transistor drain.

Example 3 includes the subject matter of any of examples 1-2, and wherein the KBC circuit comprises a second KBC transistor coupled to the first KBC transistor.

Example 4 includes the subject matter of any of examples 1-3, and wherein the first KBC transistor matches the first input transistor, and the second KBC transistor matches the precharge transistor.

Example 5 includes the subject matter of any of examples 1-4, and further comprising an output amplifier circuit comprising an output amplifier input node coupled to the first input transistor drain.

Example 6 includes the subject matter of any of examples 1-5, and wherein the KBC circuit comprises a dummy load circuit coupled to a common drain node of the first and second KBC transistors.

Example 7 includes the subject matter of any of examples 1-6, and wherein the dummy load circuit comprises a load matching an impedance at the output amplifier input node.

Example 8 includes the subject matter of any of examples 1-7, and wherein the precharge circuit comprises a precharge gate coupled to a clock node, and the second KBC transistor comprises a second KBC transistor gate coupled to a complementary clock node that provides a clock that is a complement of a clock at the clock node.

Example 9 includes the subject matter of any of examples 1-8, and wherein the first input transistor is a P-type metal oxide semiconductor (MOS) transistor.

Example 10 includes the subject matter of any of examples 1-9, and comprising a capacitor coupled to the reference input node.

Example 11 includes the subject matter of any of examples 1-10, and wherein the data input node corresponds to an input pad of a die interconnect interface.

Example 12 includes the subject matter of any of examples 1-11, and comprising a processor including an interconnect interface with a plurality of receiver cells including the dynamic comparator circuit and the kickback compensation circuit.

Example 13 is an apparatus that includes a comparator circuit, an output amplifier circuit and a compensation circuit. The comparator circuit includes a reference input node, a data input node, a first data output node, and a second data output node. The output amplifier circuit is coupled to the first and second data output nodes. The compensation circuit includes first and second compensation circuit transistors coupled to one another at the first data output node, the first compensation circuit transistor including a gate coupled to the reference input node.

Example 14 includes the subject matter of example 13, and wherein the compensation circuit comprises a dummy load circuit coupled to the first data output node.

Example 15 includes the subject matter of any of examples 13-14, and wherein the dummy load circuit comprises a load impedance corresponding to an impedance at the first data output node.

Example 16 includes the subject matter of any of examples 13-15, and wherein the comparator circuit comprises a precharge transistor with a precharge transistor gate coupled to a clock node, and the second compensation transistor comprises a second compensation transistor gate coupled to a complementary clock node.

Example 17 includes the subject matter of any of examples 13-16, and wherein the precharge transistor is an N-type metal oxide semiconductor (MOS) transistor.

Example 18 includes the subject matter of any of examples 13-17, and comprising a capacitor coupled to the reference input node.

Example 19 includes the subject matter of any of examples 13-18, and wherein the capacitor comprises a capacitance that is less than 500 fF.

Example 20 is an apparatus that includes a processor and a memory chip. The processor comprises a first interconnect interface that includes a plurality of receiver cell circuits. The memory chip comprises a second interconnect interface coupled with the first interconnect interface. The plurality of receiver cell circuits include: a dynamic comparator circuit including first and second input transistors, the first input transistor including a first gate coupled to a reference input node, and the second input transistor including a second gate coupled to a data input node, and a kickback compensation (KBC) circuit including a first KBC transistor with a first KBC transistor gate coupled to the reference input node.

Example 21 includes the subject matter of example 20, and wherein the processor is a graphics processor and the memory chip is part of a high bandwidth memory stack module.

Example 22 includes the subject matter of any of examples 20-21, and wherein the first input transistor comprises a first input transistor drain, the dynamic comparator circuit including a precharge transistor comprising a precharge transistor drain coupled to the first input transistor drain.

Example 23 includes the subject matter of any of examples 20-22, and wherein the KBC circuit comprises a second KBC transistor coupled to the first KBC transistor.

Example 24 includes the subject matter of any of examples 20-23, and wherein the first KBC transistor matches the first input transistor, and the second KBC transistor matches the precharge transistor.

Example 25 includes the subject matter of any of examples 20-24, and further comprising an output amplifier circuit comprising an output amplifier input node coupled to the first input transistor drain.

Example 26 includes the subject matter of any of examples 20-25, and wherein the KBC circuit comprises a dummy load circuit coupled to a common drain node of the first and second KBC transistors.

Example 27 includes the subject matter of any of examples 20-26, and wherein the dummy load circuit comprises a load matching an impedance at the output amplifier input node.

Example 28 includes the subject matter of any of examples 20-27, and wherein the precharge circuit comprises a precharge gate coupled to a clock node, and the second KBC transistor comprises a second KBC transistor gate coupled to a complementary clock node that provides a clock that is a complement of a clock at the clock node.

Example 29 includes the subject matter of any of examples 20-28, and wherein the first input transistor is a P-type metal oxide semiconductor (MOS) transistor.

Example 30 includes the subject matter of any of examples 20-29, and comprising a capacitor coupled to the reference input node.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures comprising the same reference numbers (or names) as the elements of any other figure can operate or function in any manner similar to that described but are not limited to such.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, a system on a chip (SoC), an application processor, an integrated circuit incorporating a combination of one or more of the aforesaid items, etc.

While the invention comprises been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a comparator circuit including first and second input transistors, the first input transistor including a first gate coupled to a reference input node, and the second input transistor including a second gate coupled to a data input node; and
a compensation circuit including a first compensation transistor with a first compensation transistor gate coupled to the reference input node.

2. The apparatus of claim 1, wherein the first input transistor comprises a first input transistor drain, the comparator circuit including a precharge transistor comprising a precharge transistor drain coupled to the first input transistor drain.

3. The apparatus of claim 2, wherein the compensation circuit comprises a second KBC transistor coupled to the first compensation transistor.

4. The apparatus of claim 3, wherein the first compensation transistor matches the first input transistor, and the second compensation transistor matches the precharge transistor.

5. The apparatus of claim 3, further comprising an output amplifier circuit comprising an output amplifier input node coupled to the first input transistor drain.

6. The apparatus of claim 3, wherein the compensation circuit comprises a dummy load circuit coupled to a common drain node of the first and second compensation transistors.

7. The apparatus of claim 6, wherein the dummy load circuit comprises a load that has an impedance response equivalent with that of the output amplifier input node.

8. The apparatus of claim 3, wherein the precharge transistor comprises a precharge transistor gate coupled to a clock node, and the second compensation transistor comprises a second compensation transistor gate coupled to a complementary clock node that provides a clock that is a complement of a clock at the clock node.

9. The apparatus of claim 1, comprising a capacitor coupled to the reference input node.

10. The apparatus of claim 1, comprising a processor including an interconnect interface with a plurality of receiver cells including the dynamic comparator circuit and the compensation circuit.

11. An apparatus, comprising:
a comparator circuit including a reference input node, a data input node, a first data output node, and a second data output node;
an output amplifier circuit coupled to the first and second data output nodes; and
a compensation circuit including first and second compensation circuit transistors coupled to one another at the first data output node, the first compensation circuit transistor including a gate coupled to the reference input node.

12. The apparatus of claim 11, wherein the compensation circuit comprises a dummy load circuit coupled to the first data output node.

13. The apparatus of claim 12, wherein the dummy load circuit comprises a load impedance corresponding to an impedance at the first data output node.

14. The apparatus of claim 11, wherein the comparator circuit comprises a precharge transistor with a precharge transistor gate coupled to a clock node, and the second compensation transistor comprises a second compensation transistor gate coupled to a complementary clock node.

15. The apparatus of claim 11, comprising a capacitor coupled to the reference input node.

16. The apparatus of claim 15, wherein the capacitor comprises a capacitance that is less than 500 fF.

17. An apparatus, comprising:
a processor comprising a first interconnect interface including a plurality of receiver cell circuits; and
a memory chip comprising a second interconnect interface coupled with the first interconnect interface, the plurality of receiver cell circuits comprising:
a comparator circuit including first and second input transistors, the first input transistor including a first gate coupled to a reference input node, and the second input transistor including a second gate coupled to a data input node, and
a compensation circuit including a first compensation transistor with a first compensation transistor gate coupled to the reference input node.

18. The apparatus of claim 17, wherein the processor is a graphics processor and the memory chip is part of a multi-memory chip stack.

19. The apparatus of claim 17, wherein the first input transistor comprises a first input transistor drain, the comparator circuit including a precharge transistor comprising a precharge transistor drain coupled to the first input transistor drain.

20. The apparatus of claim 18, wherein the compensation circuit comprises a second compensation transistor coupled to the first compensation transistor.
